(19) United States
(12) Patent Application Publication
(10) Pub. No.: US 2012/0129327 A1
(43) Pub. Date: May 24, 2012

(54) METHOD OF FABRICATING SEMICONDUCTOR DEVICE USING A HARD MASK AND DIFFUSION

(76) Inventor: Jong-Ho Lee, Gyeonggi-do (KR)

(21) Appl. No.: 12/951,622

(22) Filed: Nov. 22, 2010

(51) Int. Cl. H01L 21/225

(52) U.S. Cl. 438/548; 257/E21.148

(57) ABSTRACT

Provided is a method that can include forming a gate dielectric layer, a first diffusion layer, and a hard mask layer on a substrate defined to include first and second spaced apart regions, forming a photoresist pattern on the hard mask layer in the first region and exposing the hard mask layer on the second region, removing the exposed hard mask layer on the second region and the first diffusion layer on the second region to expose the gate dielectric layer on the second region, removing the photoresist pattern, forming a second diffusion layer on uppermost surfaces of the first and second regions, and performing a heat treatment process to diffuse a first diffusion material included in the first diffusion layer and a second diffusion material included in the second diffusion layer.

### BACKGROUND

The present inventive concept relates to a method of fabricating a semiconductor device, and more particularly, to a method of fabricating a work function control layer by using a hard mask and diffusion.

With the trend toward high-performance and high-speed semiconductor devices, attempts are being made to improve the performance of a semiconductor device, which includes both n-type field effect transistors (NFETs) and p-type field effect transistors (PFETs), by optimizing the performances of the NFETs and the PFETs. These attempts include technological advances such as modification of the structures of gates of NFETs and PFETs and the use of a high-k dielectric layer, which can have a higher dielectric constant than a silicon oxide layer, as a gate insulating layer. However, it may be difficult to fabricate a semiconductor device such that threshold voltages of NFETs and PFETs can be appropriately adjusted.

### SUMMARY

According to an aspect of the present inventive concept, there is provided a method of fabricating a semiconductor device. The method can include: forming a gate dielectric layer, a first diffusion layer, and a hard mask layer on a substrate defined to include first and second spaced apart regions, forming a photoresist pattern on the hard mask layer in the first region and exposing the hard mask layer on the second region, removing the exposed hard mask layer on the second region and the first diffusion layer on the second region to expose the gate dielectric layer on the second region, removing the photoresist pattern, forming a second diffusion layer on uppermost surfaces of the first and second regions, and performing a heat treatment process to diffuse a first diffusion material included in the first diffusion layer and a second diffusion material included in the second diffusion layer.

According to another aspect of the present inventive concept, there is provided a method of fabricating a semiconductor device. The method can include: forming a high-k insulating layer on a substrate including an NFET region and a PFET region, sequentially forming a first diffusion layer comprising a lanthanide material, and a low-temperature oxide layer on the high-k insulating layer on the NFET region, forming a second diffusion layer, comprising an aluminum material, on a top surface of the low-temperature oxide layer on the NFET region and the high-k insulating layer on the PFET region, performing a heat treatment process to form a lanthanide material-doped high-k insulating layer on the NFET region, an aluminum-doped low-temperature oxide layer on the NFET region, and an aluminum-doped high-k insulating layer on the PFET region, and removing the aluminum-doped low-temperature oxide layer.

According to another aspect of the present inventive concept, there is provided a method of fabricating a semiconductor device. The method can include: forming a high-k insulating layer on a substrate including an NFET region and a PFET region, sequentially forming a first diffusion layer, which comprises an aluminum material, and a low-temperature oxide layer on the high-k insulating layer on the PFET region, forming a second diffusion layer, comprising a lanthanide material, on a top surface of the low-temperature oxide layer on the PFET region and the high-k insulating layer on the NFET region, performing a heat treatment process to form an aluminum material-doped high-k insulating layer on the PFET region, a lanthanide material-doped low-temperature oxide layer on the PEFT region, and a lanthanide material-doped high-k insulating layer on the NFET region, and removing the lanthanide material-doped low-temperature oxide layer.

### BRIEF DESCRIPTION OF THE DRAWINGS

FIGS. 1 through 8 are cross-sectional views of structures for explaining a method of fabricating a semiconductor device according to some exemplary embodiments of the present inventive concept.

### DETAILED DESCRIPTION OF EMBODIMENTS ACCORDING TO THE INVENTIVE CONCEPT

Advantages and features of the present inventive concept and methods of accomplishing the same may be understood more readily by reference to the following detailed description of exemplary embodiments and the accompanying drawings. The present inventive concept may, however, be embodied in many different forms and should not be construed as being limited to the embodiments set forth herein. Rather, these embodiments are provided so that this disclosure will be thorough and complete and will fully convey the inventive concept to those skilled in the art, and the present inventive concept will only be defined by the appended claims. In the drawings, sizes and relative sizes of layers and regions may be exaggerated for clarity.

It will be understood that when an element or layer is referred to as being “on” another element or layer, the element or layer can be directly on another element or layer or intervening elements or layers may also be present. In contrast, when an element is referred to as being “directly on” another element or layer, there are no intervening elements or layers present. As used herein, the term “and/or” includes any and all combinations of one or more of the associated listed items.

Spatially relative terms, such as “below”, “beneath”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation, in addition to the orientation depicted in the figures. Throughout the specification, like reference numerals in the drawings denote like elements.

Embodiments according to the inventive concept are described herein with reference to plan and cross-section illustrations that are schematic illustrations of idealized embodiments of the inventive concept. As such, variations from the shapes of the illustrations as a result, for example, of manufacturing techniques and/or tolerances, are to be expected. Thus, embodiments of the inventive concept should not be construed as limited to the particular shapes of regions illustrated herein but are to include deviations in shapes that result, for example, from manufacturing. Thus, the regions illustrated in the figures are schematic in nature and their shapes are not intended to illustrate the actual shape of a region of a device and are not intended to limit the scope of the inventive concept.

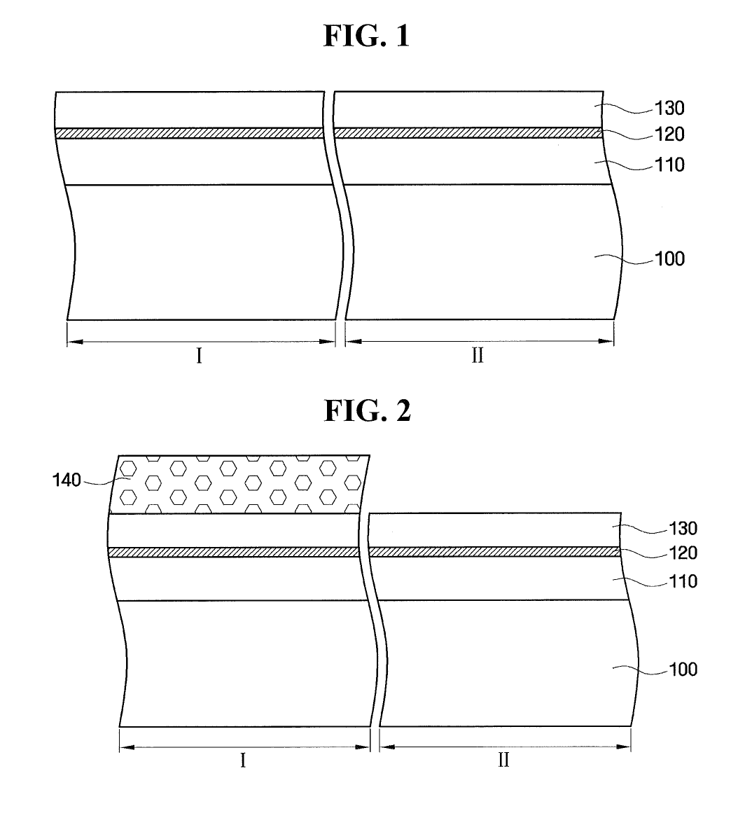

Hereinafter, a method of fabricating a semiconductor device according to some exemplary embodiments of the present inventive concept will be described with reference to FIGS. 1 through 8. FIGS. 1 through 8 are cross-sectional views of structures for explaining a method of fabricating a semiconductor device according to some exemplary embodiments of the present inventive concept. For simplicity, a source region, a drain region, and a device isolation region such as a shallow trench isolation (STI) region are not illustrated in FIGS. 1 through 8.

Referring to FIG. 1, a gate dielectric layer 110, a first diffusion layer 120, and a hard mask layer 130 are sequentially formed on a substrate 100 which includes a first region I and a second region II.

The first region I and the second region II are defined in the substrate 100. The first region I may be an n-type field effect transistor (NFET) region, and the second region II may be a p-type field effect transistor (PFET) region. Conversely, the first region I may be the PFET region, and the second region II may be the NFET region. The following description will basically address a case where the first region I is the NFET region and the second region II is the PFET region. However, a case where the first region I is the PFET region and the second region II is the NFET region will additionally be described.

The substrate 100 may be a bulk silicon substrate or a silicon-on-insulator (SOI) substrate. Alternatively, the substrate 100 may be a silicon substrate or may contain other materials such as, but not limited to, germanium, indium antimonide, lead telluride, indium arsenide, indium phosphide, gallium arsenide, or gallium antimonide.

The gate dielectric layer 110 may be a high-k insulating layer containing a high-k dielectric material. For example, the gate dielectric layer 110 may contain at least one of halfnium oxynitride (HfON), hafnium silicon oxynitride (HfSiON), zirconium oxynitride (ZrON), and zirconium silicon oxynitride (ZrSiON). Further, examples of high-k dielectric materials used to form the gate dielectric layer 110 may include at least one of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, and a nitride materials thereof.

Next, the first diffusion layer 120 is formed on the gate dielectric layer 110. Here, the first diffusion layer 120 may be formed directly on the gate dielectric layer 110. When the first region I is the NFET region, the first diffusion layer 120 may contain a lanthanide material as a first diffusion material. Examples of lanthanide materials may include, but are not limited to, at least one of lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), and lutetium (Lu).

When the first region I is the PFET region, the first diffusion layer 120 may contain an aluminum material as the first diffusion material.

The first diffusion material in the first diffusion layer 120 is diffused into the gate dielectric layer 110 by a heat treatment process which will be described later. Accordingly, the gate dielectric layer 110 may be transformed into a work function control layer having an appropriate work function for an NFET or a PFET.

Next, the hard mask layer 130 is formed on the first diffusion layer 120. The hard mask layer 130 may be, for example, a low-temperature oxide layer. More specifically, the hard mask layer 130 may be deposited in a low-temperature atmosphere. For example, the hard mask layer 130 may be deposited using, but not limited to, a low-temperature deposition process such as atomic layer deposition (ALD). Low-temperature oxide layers typically have a relatively low density compared with thermal oxide layers. Thus, the hard mask layer 130 can be easily removed in a subsequent process.

Next, referring to FIG. 2, a photoresist pattern 140 is formed on the hard mask layer 130 to expose the hard mask layer 130 on the second region II. Here, a developable material, such as a developable bottom anti-reflective coating (DBARC), may not be formed under the photoresist pattern 140. That is, the photoresist pattern 140 without the DBARC may be formed directly on the hard mask layer 130. Since the hard mask layer 130 is interposed between the photoresist pattern 140 and the first diffusion layer 120, the first diffusion layer 120 does not directly contact the photoresist pattern 140. Therefore, the first diffusion layer 120 does not react with the photoresist pattern 140 and thus remains stable. In addition, since DBARC is not used, the damage to an underlying layer by the removal of the DBARC can be reduced.

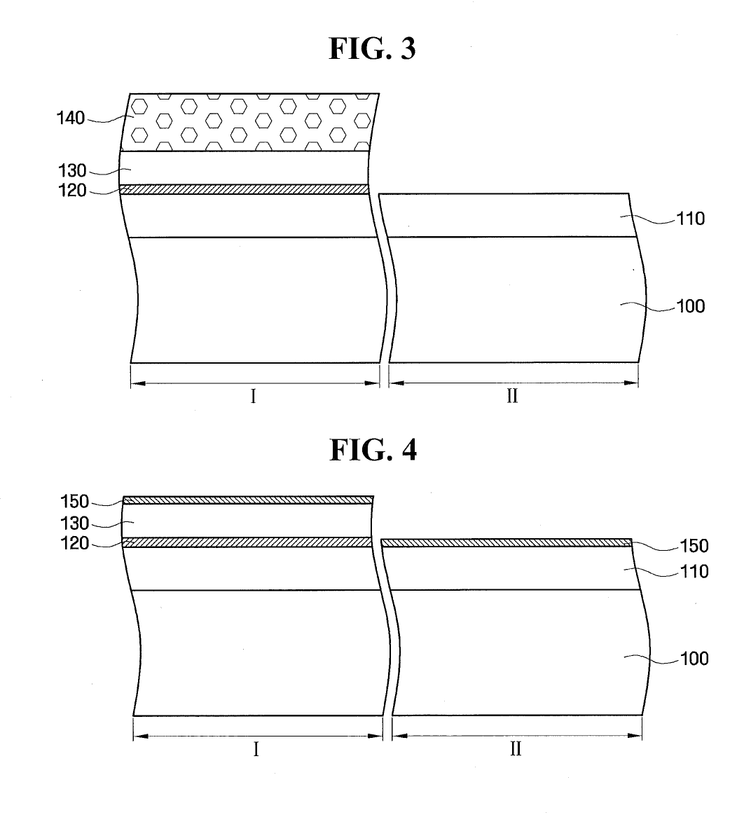

Next, referring to FIG. 3, the hard mask layer 130 exposed by the photoresist pattern 140 and the first diffusion layer 120 on the second region II are removed.

More specifically, the hard mask layer 130 and the first diffusion layer 120 may be simultaneously or sequentially removed by using the photoresist pattern 140 as a mask. A wet-etching process or a dry-etching process may be performed. To reduce plasma damage, wet-etching process may be performed. The wet-etching process may be performed using an etchant that is a mixture of hydrochloric acid (HCl) and one of hydrofluoric acid (HF), diluted HF (DHF), and buffered HF (BHF).

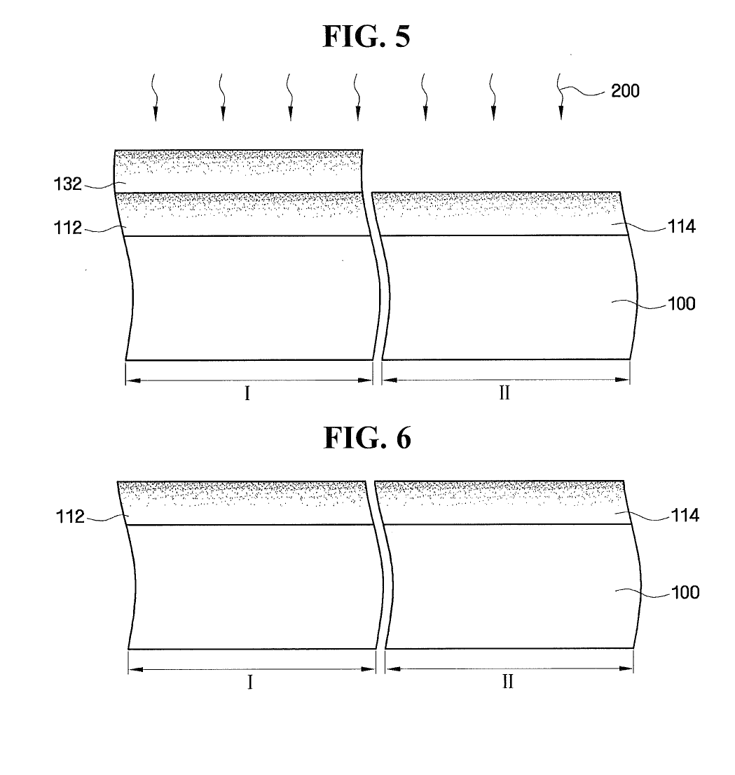

Accordingly, the hard mask layer 130 may remain on the first diffusion layer 120 formed on the first region I. The hard mask layer 130 remaining on the first region I can prevent the first diffusion layer 120 and the photoresist pattern 140 from directly contacting each other and simplify the process of forming a first work function control layer 112 and a second work function control layer 114 (see for example FIG. 5).

Referring to FIG. 4, the photoresist pattern 140 is removed, and a second diffusion layer 150 is formed on the uppermost surfaces on the substrate 100.

More specifically, the photoresist pattern 140 may be removed using an ashing process. For example, reactive ion etching (RIE) may be used. When the first region I is the NFET region, the RIE process may be performed at high pH conditions, thereby reducing damage to the first diffusion layer 120.

Then, the second diffusion layer 150 may be formed on the whole surface of the substrate 100 from which the photoresist pattern 140 has been removed. More specifically, the second diffusion layer 150 may be formed on a top surface of the hard mask layer 130 on the first region I and a top surface of the gate dielectric layer 110 on the second region II. As described above, when the first region I is the NFET region, the second diffusion layer 150 may contain an aluminum material as a second diffusion material. Likewise, when the first region I is the PFET region, the second diffusion layer 150 may contain a lanthanide material as the second diffusion material. Specific examples of lanthanide materials are substantially the same as those described above.

When the first region I is the NFET region and the second region II is the PFET region, the second diffusion layer 150 containing aluminum may be formed on the top surface of the hard mask layer 130 (e.g., a low-temperature oxide layer) on the NFET region and the top surface of the gate dielectric layer 110 (e.g., a high-k insulating layer) on the PFET region. Further, the first diffusion layer 120 containing a lanthanide material may be disposed under the hard mask layer 130 on the NFET region. That is, the gate dielectric layer 110, the first diffusion layer 120 containing a lanthanide material, the hard mask layer 130, and the second diffusion layer 150 containing aluminum may be sequentially deposited on the NFET region of the substrate 100, and the gate dielectric layer 110 and the second diffusion layer 150 containing aluminum may be sequentially deposited on the PFET region.

When the first region I is the PFET region and the second region II is the NFET region, the second diffusion layer 150 containing a lanthanide material may be formed on the top surface of the hard mask layer 130 (e.g., a low-temperature oxide layer) on the PFET region and the top surface of the gate dielectric layer 110 (e.g., a high-k insulating layer) on the PFET region. Further, the first diffusion layer 120 containing aluminum may be disposed under the hard mask layer 130 on the PFET region. That is, the gate dielectric layer 110, the first diffusion layer 120 containing aluminum, the hard mask layer 130, and the second diffusion layer 150 containing a lanthanide material may be sequentially deposited on the PFET region of the substrate 100, and the gate dielectric layer 110 and the second diffusion layer 150 containing a lanthanide material may be sequentially deposited on the NFET region of the substrate 100.

The first diffusion layer 120 is formed on the gate dielectric layer 110 on the first region I, and the second diffusion layer 150 is formed on the gate dielectric layer 110 on the second region II. Here, the first diffusion layer 120 and the second diffusion layer 150 may be formed directly on the gate dielectric layer 110. That is, the first diffusion layer 120 and the second diffusion layer 150 may be formed on the gate dielectric layer 110 on the first region I and the second region II to directly contact the gate dielectric layer 110. Further, the second diffusion layer 150 may be formed directly on the hard mask layer 130 on the first region I to contact the hard mask layer 130.

Next, referring to FIG. 5, a heat treatment process 200 is performed to diffuse the first diffusion material of the first diffusion layer 120 and the second diffusion material of the second diffusion layer 150.

More specifically, the heat treatment process 200 is performed on the substrate 100 having the first diffusion layer 120 and the second diffusion layer 150, thereby diffusing the first diffusion material and the second diffusion material to the underlying layer. That is, as a result of the heat treatment process 200, the second diffusion material of the second diffusion layer 150 formed on the hard mask layer 130 may diffuse into the hard mask layer 130. In addition, the first and second diffusion materials of the first and second diffusion layers 120 and 150 formed on the gate dielectric layer 110 on the first region I and the second region II may diffuse into the gate dielectric layer 110.

In other words, the heat treatment process 200 may cause the first diffusion material to diffuse into the gate dielectric layer 110 on the first region I, thereby forming the first work function control layer 112. In addition, the heat treatment process 200 may cause the second diffusion material to diffuse into the gate dielectric layer 110 on the second region, thereby forming the second work function control layer 114. Here, the second diffusion material of the second diffusion layer 150 on the first region I may diffuse into the hard mask layer 130 on the first region I. As a result, the hard mask layer 130 doped with the second diffusion material may be formed.

When the first region I is the NFET region while the second region II is the PFET region, the first work function control layer 112 may be the gate dielectric layer 110 doped with a lanthanide material, e.g., a high-k insulating layer doped with a lanthanide material, and the second work function control layer 114 may be the gate dielectric layer 110 doped with aluminum, e.g., a high-k insulating layer doped with aluminum. In addition, the hard mask layer 130 on the first region I may be the hard mask layer 130 doped with aluminum, for example, a low-temperature oxide layer doped with aluminum.

Conversely, when the first region I is the PFET region while the second region II is the NFET region, the first work function control layer 112 may be the gate dielectric layer 110 doped with aluminum, e.g., a high-k insulating layer doped with aluminum, and the second work function control layer 114 may be the gate dielectric layer 110 doped with a lanthanide material, e.g., a high-k insulating layer doped with a lanthanide material. In addition, the hard mask layer 130 on the first region I may be the hard mask layer 130 doped with a lanthanide material, e.g., a low-temperature oxide film doped with a lanthanide material.

The heat treatment process 200 may be, for example, an annealing process. Processing conditions of the heat treatment process 200, for example, the processing temperature and/or processing time may be determined in view of characteristics of the first and second diffusion materials, diffusion profiles of the first and second diffusion materials within the gate dielectric layer 110, or the like.

Referring to FIG. 6, the hard mask layer 130 (indicated by reference numeral 132 in FIG. 5) is removed.

The hard mask layer 130 doped with the second diffusion material is removed, thereby exposing the first work function control layer 112 and the second work function control layer 114. Accordingly, the first work function control layer 112 may be formed on the first region I of the substrate 100, and the second work function control layer 114 may be formed on the second region II of the substrate 100. That is, since the hard mask layer 130 is formed on the first diffusion layer 120 on the first region I, even if the heat treatment process 200 (see FIG. 5) is performed, the second diffusion material of the second diffusion layer 150 does not affect the first diffusion layer 120 and the gate dielectric layer 110 on the first region I. That is, the process of forming the first work function control layer 112 and the second work function control layer 114 respectively on the first region I and the second region II may be simplified.

When the first region I is the NFET region while the second region II is the PFET region, the hard mask layer 130 may be a low-temperature oxide layer doped with aluminum. In this case, the low-temperature oxide layer may be removed to expose a high-k insulating layer doped with a lanthanide material and formed on the NFET region of the substrate 100 and to expose a high-k insulating layer doped with aluminum and formed on the PFET region of the substrate 100. Similarly, when the first region I is the PFET region while the second region II is the NFET region, the hard mask layer 130 may be a low-temperature oxide layer doped with a lanthanide material. In this case, the low-temperature oxide layer may be removed to expose a high-k insulating layer doped with aluminum and formed on the PFET region of the substrate 100 and to expose a high-k insulating layer doped with a lanthanide material and formed on the NFET region of the substrate 100.

As described above, when the hard mask layer 130 is formed as a low-temperature oxide layer, it is easier to remove the hard mask layer 130 since low-temperature oxide layers have a relatively low density compared with thermal oxide layers. Therefore, the surface of the gate dielectric layer 110 can remain intact despite the removal of the hard mask layer 130. More specifically, while the top surface of the gate dielectric layer 110 on the first region I is in contact with the hard mask layer 130, the hard mask layer 130 can be readily removed for a relatively short time due to characteristics of the low-temperature oxide layer. Thus, the top surface of the gate dielectric layer 110 on the first region I, which was in contact with the hard mask layer 130, can remain intact even after the removal of the hard mask layer 130.

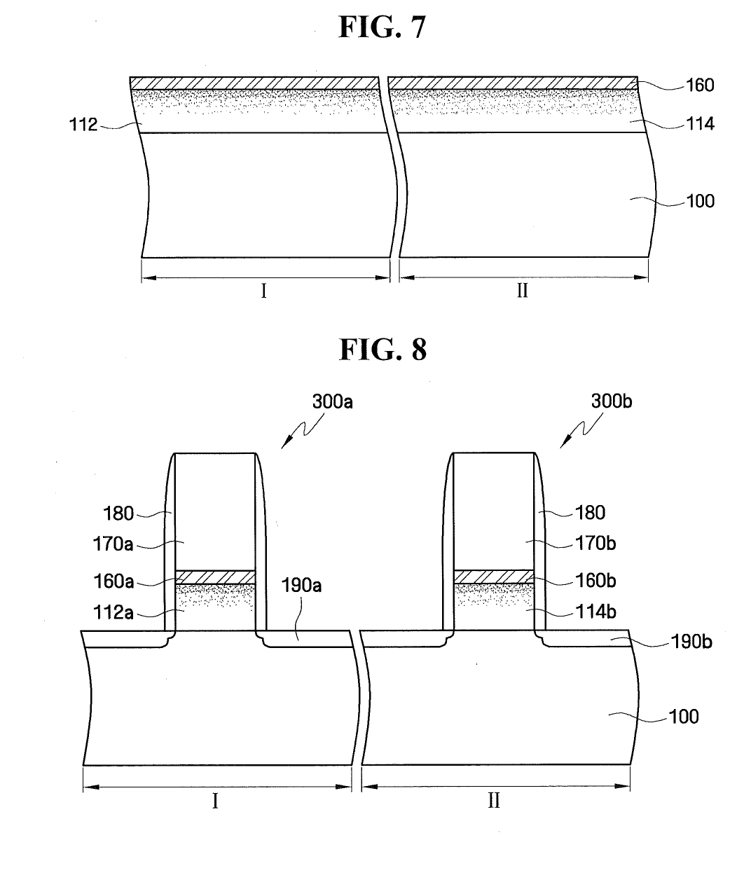

Next, referring to FIG. 7, after the hard mask layer 130 is removed, a metal gate layer 160 may be formed on the gate dielectric layer 110 into which the first diffusion material and the second diffusion material have diffused.

More specifically, the metal gate layer 160 may be formed on the first work function control layer 112 and the second work function control layer 114 by using, e.g., sputtering. The metal gate layer 160 may be a single layer. For example, the metal gate layer 160 may contain at least one of titanium nitride (TiN), tantalum nitride (TaN), titanium aluminum nitride (TiAIN), tantalum nitride/titanium nitride, tantalum carbide (TaC), and tantalum carbo-nitride (TaCN). However, examples of materials that can be used to form the metal gate layer 160 are not limited to the above materials.

Next, referring to FIG. 8, the metal gate layer 160, the first work function control layer 112, and the second work function control layer 114 are patterned to form a first metal gate structure 300a and a second metal gate structure 300b.

As shown in the drawing, after the metal gate layer 160 (see FIG. 7) is formed, a silicon layer (not shown), for example, a silicon layer containing amorphous silicon, may be formed on the metal gate layer 160. Then, a mask pattern is formed on the silicon layer, and the silicon layer, the metal gate layer 160, the first work function control layer 112, and the second work function control layer 114 are sequentially patterned using the mask pattern as an etch mask. As a result, the first and second metal gate structures 300a and 300b respectively including first and second work function control layers 112a and 114b and metal gate layers 160a and 160b, and silicon layers 170a and 170b are formed. The patterning process may be performed using a dry-etching process or a wet-etching process.

Next, source and drain regions 190a and 190b are formed by performing processes well-known to those of ordinary skill in the field of semiconductor devices, and spacers 180 are formed on both sidewalls of each of the first and second metal gate structures 300a and 300b.

A backend process including the formation of wiring to enable the input and output of electrical signals to/from each transistor, formation of a passivation layer on the substrate 100, and packaging the substrate 100 may further be performed, thereby completing the semiconductor device.

While the present inventive concept has been particularly shown and described with reference to exemplary embodiments thereof, it will be understood by those of ordinary skill in the art that various changes in form and detail may be made therein without departing from the spirit and scope of the present inventive concept as defined by the following claims. The exemplary embodiments should be considered in a descriptive sense only and not for purposes of limitation.

1. A method of fabricating a semiconductor device, the method comprising:
forming a gate dielectric layer, a first diffusion layer, and a hard mask layer on a substrate defined to include first and second spaced apart regions, wherein the hard mask layer comprises a low-temperature oxide layer;
forming a photoresist pattern on the hard mask layer in the first region and exposing the hard mask layer on the second region;
removing the exposed hard mask layer on the second region and the first diffusion layer on the second region to expose the gate dielectric layer on the second region, by a wet-etching process performed using an etchant that is a mixture of HCl and one of HF, DHF, and BHF;
removing the photoresist pattern;
forming a second diffusion layer on uppermost surfaces of the first and second regions; and
performing a heat treatment process to diffuse a first diffusion material included in the first diffusion layer and a second diffusion material included in the second diffusion layer, wherein the second diffusion material included in the second diffusion layer diffuses into the hard mask layer.

2. The method of claim 1, wherein the forming the second diffusion layer on uppermost surfaces of the first and second regions comprises forming the second diffusion layer on a top surface of the hard mask layer on the first region and on a top surface of the gate dielectric layer on the second region.

3. The method of claim 1, wherein performing the heat treatment comprises diffusing the first diffusion material into the gate dielectric layer on the first region to form a first work function control layer and diffusing the second diffusion material into the gate dielectric layer on the second region to form a second work function control layer.

4. The method of claim 3 further comprising:
removing the hard mask layer, wherein the second diffusion material diffused therein is removed.

5. The method of claim 1, wherein the first diffusion material comprises a lanthanide material, and the second diffusion material comprises aluminum.

6. The method of claim 5, wherein the first region comprises an n-type field effect transistor (NFET) region wherein an NFET is formed, and the second region is a p-type field effect transistor (PFET) region wherein an PFET is formed.

7. The method of claim 1, wherein the first diffusion material comprises an aluminum material and the second diffusion material comprises a lanthanide material.

8. The method of claim 7, wherein the first region comprises a p-type field effect transistor (PFET) region wherein an PFET is formed and the second region comprises an n-type field effect transistor (NFET) region wherein an NFET is formed.

9. (canceled)

10. The method of claim 1, further comprising:
removing the hard mask layer including the second diffusion material diffused therein.

11. The method of claim 1, further comprising:
removing the hard mask layer; and then
forming a metal gate layer on the gate dielectric layer, into which the first diffusion material and the second diffusion material have diffused.

12. The method of claim 11, wherein the metal gate layer comprises a single layer.

13. The method of claim 1, wherein the gate dielectric layer comprises a high-k dielectric material.

14. The method of claim 1, wherein the gate dielectric layer comprises at least one of halfnium oxynitride (HfON), hafnium silicon oxynitride (HfSiON), zirconium oxynitride (ZrON), and zirconium silicon oxynitride (ZrSiON).

15. A method of fabricating a semiconductor device, the method comprising:
forming a high-k insulating layer on a substrate including an NFET region and a PFET region;
sequentially forming a first diffusion layer comprising a lanthanide material, and a low-temperature oxide layer on the high-k insulating layer on the NFET region and the PFET region;
removing the first diffusion layer on the PFET region and the low-temperature oxide layer on the PFET region, by a wet-etching process performed using an etchant that is a mixture of HCl and one of HF, DHF, and BHF;
forming a second diffusion layer, comprising an aluminum material, on a top surface of the low-temperature oxide layer on the NFET region and the high-k insulating layer on the PFET region;
performing a heat treatment process to form a lanthanide material-doped high-k insulating layer on the NFET region, an aluminum-doped low-temperature oxide layer on the NFET region, and an aluminum-doped high-k insulating layer on the PFET region; and
removing the aluminum-doped low-temperature oxide layer.

16. The method of claim 15, further comprising:
forming a metal gate layer on the high-k insulating layer after the removing of the aluminum-doped low-temperature oxide layer.

17. The method of claim 16, wherein the metal gate layer comprises a single layer.

18. A method of fabricating a semiconductor device, the method comprising:
forming a high-k insulating layer on a substrate including an NFET region and a PFET region;
sequentially forming a first diffusion layer, which comprises an aluminum material, and a low-temperature oxide layer on the high-k insulating layer on the NFET region and the PFET region;
removing the first diffusion layer on the NFET region and the low-temperature oxide layer on the NFET region, by a wet-etching process performed using an etchant that is a mixture of HCl and one of HF, DHF, and BHF;
forming a second diffusion layer, comprising a lanthanide material, on a top surface of the low-temperature oxide layer on the PFET region and the high-k insulating layer on the NFET region;
performing a heat treatment process to form an aluminum material-doped high-k insulating layer on the PFET region, a lanthanide material-doped low-temperature oxide layer on the PFET region, and a lanthanide material-doped high-k insulating layer on the NFET region; and
removing the lanthanide material-doped low-temperature oxide layer.

19. The method of claim 18, further comprising:
forming a metal gate layer on the high-k insulating layer after removing the lanthanide material-doped low-temperature oxide layer.

20. The method of claim 19, wherein the metal gate layer comprises a single layer.
